(19) United States
(12) Patent Application Publication
(10) Pub. No.: US 2025/0374566 A1
(43) Pub. Date: Dec. 4, 2025

(54) CAPACITOR STRUCTURE AND MANUFACTURING METHOD THEREOF

(71) Applicant: United Microelectronics Corp., Hsin-Chu City (TW)

(72) Inventors: Da-Jun Lin, Kaohsiung City (TW); Yao-Hsien Chung, Tainan City (TW); Fu-Yu Tsai, Tainan City (TW); Bin-Siang Tsai, Changhua County (TW)

(73) Assignee: United Microelectronics Corp., Hsin-Chu City (TW)

(21) Appl. No.: 18/770,622

(22) Filed: Jul. 11, 2024

(30) Foreign Application Priority Data
May 31, 2024 (TW) 113120245

(51) Int. Cl. H10D 1/68; H10D 1/00

(52) U.S. Cl. CPC H10D 1/696; H10D 1/042; H10D 1/043; H10D 1/716

(57) ABSTRACT

A capacitor structure includes a dielectric stack structure, a bottom electrode, a top electrode, and a capacitor dielectric layer. The dielectric stack structure is disposed on a substrate and includes a stop layer and a dielectric layer disposed on the stop layer. The bottom electrode is disposed in the dielectric stack structure. The top electrode is disposed above the substrate. The bottom electrode surrounds the top electrode in a horizontal direction. The capacitor dielectric layer is disposed between the bottom electrode and the top electrode. The bottom electrode includes a first dual damascene structure surrounding the capacitor dielectric layer and the top electrode in the horizontal direction. An upper portion of the first dual damascene structure is disposed in the dielectric layer. A lower portion of the first dual damascene structure is partly disposed in the dielectric layer. The lower portion penetrates through the stop layer in a vertical direction.

### BACKGROUND OF THE INVENTION

### 1. Field of the Invention

The present invention relates to a capacitor structure and a manufacturing method thereof, and more particularly, to a capacitor structure including a bottom electrode with dual damascene structure and a manufacturing method thereof.

### 2. Description of the Prior Art

In modern society, the micro-processor systems composed of integrated circuits (ICs) are applied popularly in our living. Many electrical products, such as personal computers, mobile phones, and home appliances, include ICs. With the development of technology and the increasingly imaginative applications of electrical products, the design of ICs tends to be smaller, more delicate and more diversified.

In the recent electrical products, IC devices, such as metal oxide semiconductor (MOS) transistors, capacitors, or resistors, are produced from silicon based substrates that are fabricated by semiconductor manufacturing processes. A complicated IC system may be composed of the IC devices electrically connected with one another. Generally, a capacitor structure may be composed of a top electrode, a dielectric layer, and a bottom electrode. The capacitor structure is traditionally disposed in an inter-metal dielectric (IMD) layer on a silicon based substrate and includes a metal-insulator-metal (MIM) structure. However, as the demands for more functions and higher performance of the electrical products increase continually, the complexity and the integrity of the ICs increase also, and the space for forming the capacitor structures becomes smaller relatively. Accordingly, the capacitance of the traditional capacitor structure is limited, and the related problems about the IC design may be generated.

### SUMMARY OF THE INVENTION

A capacitor structure and a manufacturing method thereof are provided in the present invention. A bottom electrode with a dual damascene structure is disposed in a dielectric stack structure and surrounds a capacitor dielectric layer and a top electrode for increasing capacitance of the capacitor structure and/or enhancing operation performance of the capacitor structure.

According to an embodiment of the present invention, a capacitor structure is provided. The capacitor structure includes a dielectric stack structure, a bottom electrode, a top electrode, and a capacitor dielectric layer. The dielectric stack structure is disposed on a substrate, and the dielectric stack structure includes a stop layer and a dielectric layer disposed on the stop layer. The bottom electrode is disposed in the dielectric stack structure. The top electrode is disposed above the substrate, and the bottom electrode surrounds the top electrode in a horizontal direction. The capacitor dielectric layer is disposed between the bottom electrode and the top electrode, and the bottom electrode includes a first dual damascene structure surrounding the capacitor dielectric layer and the top electrode in the horizontal direction. An upper portion of the first dual damascene structure is disposed in the dielectric layer, a lower portion of the first dual damascene structure is partly disposed in the dielectric layer, and the lower portion of the first dual damascene structure penetrates through the stop layer in a vertical direction.

According to another embodiment of the present invention, a manufacturing method of a capacitor structure is provided. The manufacturing method includes the following steps. A dielectric stack structure and a bottom electrode are formed on a substrate. The bottom electrode is located in the dielectric stack structure, and the bottom electrode includes a pad structure and a first dual damascene structure disposed on the pad structure. A width of a lower portion of the first dual damascene structure is less than a width of an upper portion of the first dual damascene structure, and a part of the dielectric stack structure is surrounded by the bottom electrode in a horizontal direction. At least a part of the dielectric stack structure surrounded by the bottom electrode in the horizontal direction is removed for forming a trench surrounded by the bottom electrode in the horizontal direction. A metal-insulator-metal (MIM) capacitor is formed after the trench is formed. At least a part of the MIM capacitor is formed in the trench and formed conformally on surfaces of the first dual damascene structure and the pad structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a capacitor structure according to a first embodiment of the present invention.

FIG. 2 is a top view schematic drawing illustrating a bottom electrode according to an embodiment of the present invention.

FIG. 3 is a top view schematic drawing illustrating a bottom electrode according to an embodiment of the present invention.

FIG. 4 is a top view schematic drawing illustrating a bottom electrode according to an embodiment of the present invention.

FIG. 5 is a top view schematic drawing illustrating a bottom electrode according to an embodiment of the present invention.

FIGS. 6-11 are schematic drawings illustrating a manufacturing method of a capacitor structure according to an embodiment of the present invention, wherein FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, and FIG. 11 is a schematic drawing in a step subsequent to FIG. 10.

FIG. 12 is a schematic drawing illustrating a capacitor structure according to a second embodiment of the present invention.

FIG. 13 is a schematic drawing illustrating a capacitor structure according to a third embodiment of the present invention.

FIG. 14 is a schematic drawing illustrating a capacitor structure according to a fourth embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

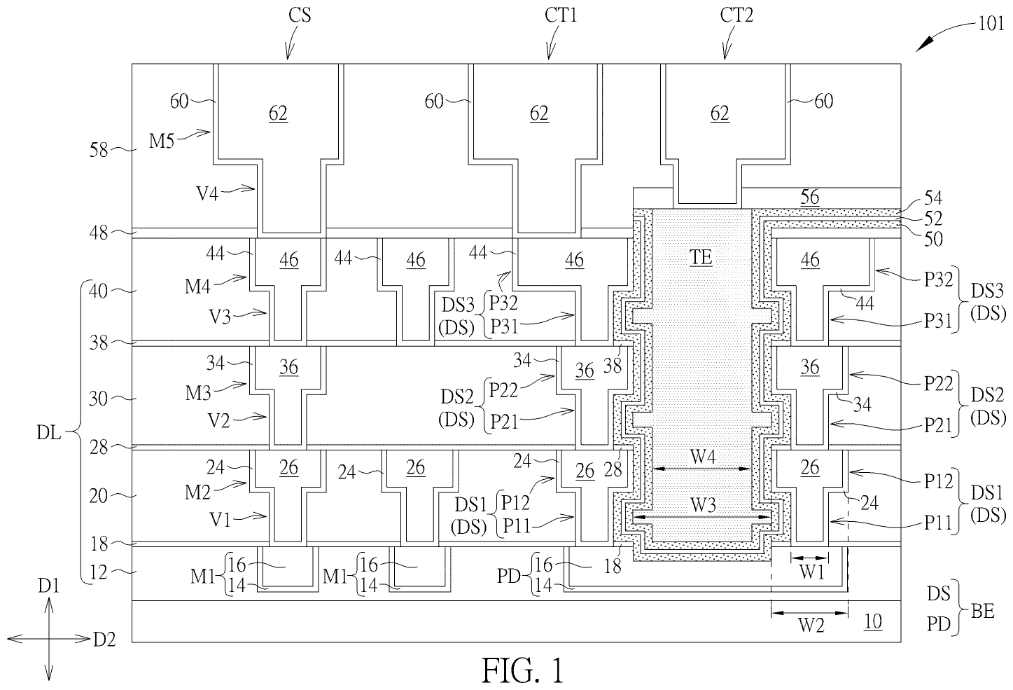

Please refer to FIG. 1. FIG. 1 is a schematic drawing illustrating a capacitor structure 101 according to a first embodiment of the present invention. As shown in FIG. 1, the capacitor structure 101 includes a dielectric stack structure DL, a bottom electrode BE, a top electrode TE, and a capacitor dielectric layer 52. The dielectric stack structure DL is disposed on a substrate 10, and the bottom electrode BE is disposed in the dielectric stack structure DL. The top electrode TE is disposed above the substrate 10, and the bottom electrode BE surrounds the top electrode TE in a horizontal direction (such as a horizontal direction D2, but not limited thereto). The capacitor dielectric layer 52 is disposed between the bottom electrode BE and the top electrode TE, and the bottom electrode BE includes a first dual damascene structure DS1 surrounding the capacitor dielectric layer 52 and the top electrode TE in the horizontal direction D2. The dual damascene structure formed in the dielectric stack structure DL may be used to compose at least a part of the bottom electrode BE for increasing the surface area of the capacitor dielectric layer 52 so as to increase the capacitance and/or improving the operation performance of the capacitor structure (such as improving the Q-factor, but not limited thereto) with the low electrical resistance property of the dual damascene structure.

In some embodiments, the substrate 10 may include a semiconductor substrate, such as a silicon substrate, a silicon germanium semiconductor substrate, a silicon-on-insulator (SOI) substrate, or a substrate made of other suitable materials. In addition, a device layer (not illustrated) may be disposed between the substrate 10 and the dielectric stack structure DL, and the device layer may include active elements (such as transistors, diodes, and so forth), passive elements, and/or other related circuits. In some embodiments, the dielectric stack structure DL may include a plurality of dielectric layers (such as a dielectric layer 12, a dielectric layer 20, a dielectric layer 30, and a dielectric layer 40) and a plurality of stop layers (such as a stop layer 18, a stop layer 28, and a stop layer 38) alternately disposed in a vertical direction D1. The capacitor structure may further include an interconnection structure CS, and at least a part of the interconnection structure CS is disposed in the dielectric stack structure DL. The interconnection structure CS may include a plurality of conductive lines (such as a conductive line M1, a conductive line M2, a conductive line M3, a conductive line M4, and a conductive line M5) and a plurality of via conductors (such as a via conductor V1, a via conductor V2, a via conductor V3, and a via conductor V4) alternately disposed in the vertical direction D1 and electrically connected with one another, and the interconnection structure CS may be electrically connected with the elements and/or circuits in the device layer described above, but not limited thereto. In some embodiments, the conductive line and the corresponding via conductor may have a dual damascene structure, and a dual damascene structure DS in the bottom electrode BE and the dual damascene structure in the interconnection structure CS may be formed concurrently by the same process for process simplification, but not limited thereto. In addition, the device layer described above may be formed by the front end of line (FEOL) process in the semiconductor manufacturing process, the dielectric stack structure DL and the interconnection structure CS may be formed by the back end of line (BEOL) process in the semiconductor manufacturing process, and the manufacturing method of a capacitor unit in the capacitor structure 101 may be integrated with the BEOL process accordingly, but not limited thereto.

In some embodiments, the vertical direction D1 described above may be regarded as a thickness direction of the substrate 10. The substrate 10 may have a top surface and a bottom surface opposite to the top surface in the vertical direction D1, and the dielectric stack structure DL, the bottom electrode BE, the top electrode TE, the capacitor dielectric layer 52, and the interconnection structure CS described above may be disposed at the side of the top surface of the substrate 10. A horizontal direction substantially orthogonal to the vertical direction D1 (such as a horizontal direction D2 or other direction orthogonal to the vertical direction D1) may be substantially parallel with the top surface and/or the bottom surface of the substrate 10, but not limited thereto. In this description, a distance between the bottom surface of the substrate 10 and a relatively higher location and/or a relatively higher part in the vertical direction D1 may be greater than a distance between the bottom surface of the substrate 10 and a relatively lower location and/or a relatively lower part in the vertical direction D1. The bottom or a lower portion of each component may be closer to the bottom surface of the substrate 10 in the vertical direction D1 than the top or upper portion of this component. Another component disposed above a specific component may be regarded as being relatively far from the bottom surface of the substrate 10 in the vertical direction D1, and another component disposed under a specific component may be regarded as being relatively close to the bottom surface of the substrate 10 in the vertical direction D1. In this description, a top surface of a specific component may include the topmost surface of this component in the vertical direction D1, and a bottom surface of a specific component may include the bottommost surface of this component in the vertical direction D1, but not limited thereto. Additionally, in this description, the condition that a certain component is disposed between two other components in a specific direction may include but is not limited to a condition that the certain component is sandwiched between the two other components in the specific direction.

In some embodiments, the bottom electrode BE may include a pad structure PD and one or a plurality of dual damascene structures DS (such as the first dual damascene structure DS1 and/or a second dual damascene structure DS2) disposed on and electrically connected with the pad structure PD, and the dual damascene structures DS may surround the capacitor dielectric layer 52 and the top electrode TE in the horizontal direction. A width of a lower portion of each of the dual damascene structures DS is less than a width of an upper portion of each of the dual damascene structures DS, and the inner sidewall of the bottom electrode BE surrounding the capacitor dielectric layer 52 and the top electrode TE may have a recessed structure for increasing the surface area of the capacitor dielectric layer 52 accordingly and achieving the purpose of enhancing capacitance. For example, the bottom electrode BE may include the first dual damascene structure DS1, the second dual damascene structure DS2, and a third dual damascene structure DS3 sequentially disposed in the vertical direction D1 and connected with one another. The second dual damascene structure DS2 is disposed on the first dual damascene structure DS1, and the third dual damascene structure DS3 is disposed on the second dual damascene structure DS2 accordingly, but not limited thereto. A width of a lower portion P11 of the first dual damascene structure DS1 (such as a width W1) is less than a width of an upper portion P12 of the first dual damascene structure DS1 (such as a width W2), a width of a lower portion P21 of the second dual damascene structure DS2 is less than a width of an upper portion P22 of the second dual damascene structure DS2, and a width of a lower portion P31 of the third dual damascene structure DS3 is less than a width of an upper portion P32 of the third dual damascene structure DS3. The lower portion P11 of the first dual damascene structure DS1 may be directly connected with the pad structure PD and the upper portion P12, respectively, the lower portion P21 of the second dual damascene structure DS2 may be directly connected with the upper portion P22 and the upper portion P12 of the first dual damascene structure DS1, respectively, and the lower portion P31 of the third dual damascene structure DS3 may be directly connected with the upper portion P32 and the upper portion P22 of the second dual damascene structure DS2, respectively.

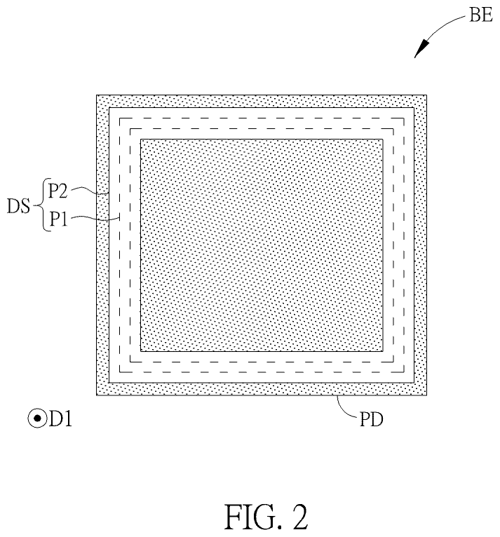

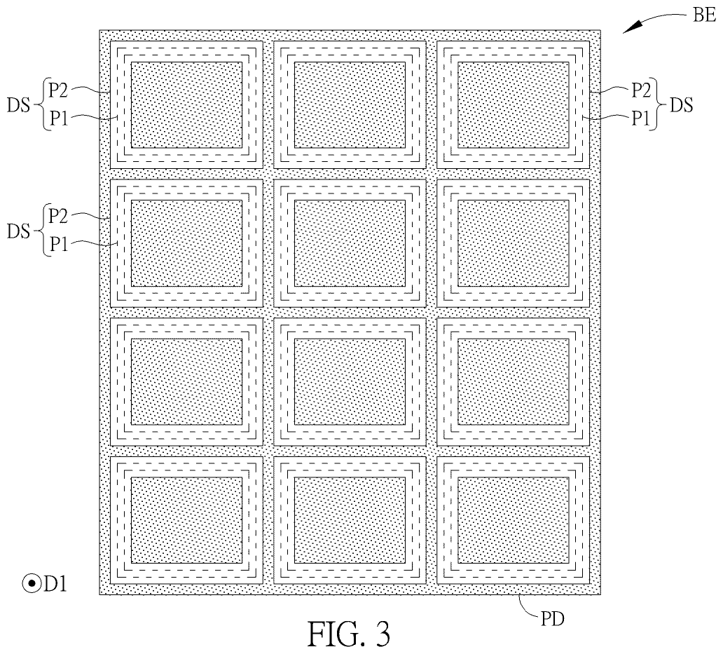

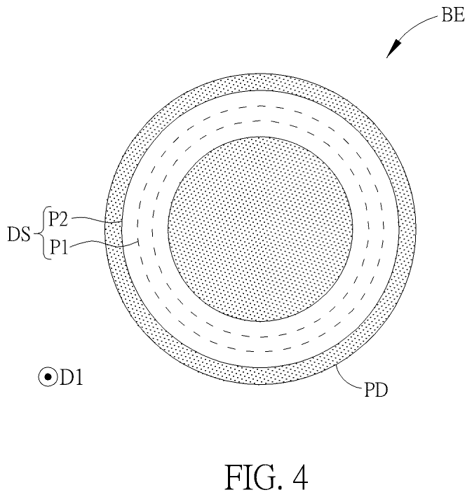

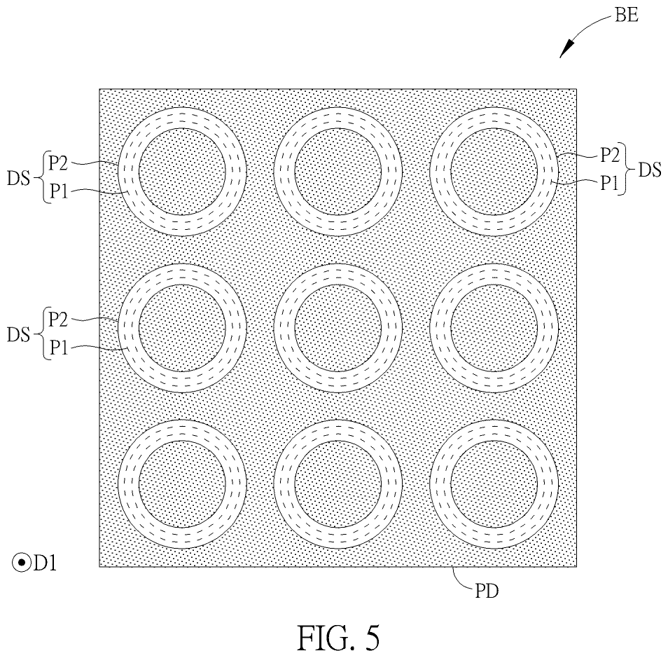

Please refer to FIGS. 1-5. FIGS. 2-5 are top view schematic drawings illustrating the bottom electrodes BE in different embodiments, respectively. In FIGS. 2-5, the dual damascene structure DS may represent the first dual damascene structure DS1, the second dual damascene structure DS2, or the third dual damascene structure DS3 in FIG. 1, and a lower portion P1 and an upper portion P2 of the dual damascene structure DS may represent the lower portion and the upper portion of the first dual damascene structure DS1, the second dual damascene structure DS2, or the third dual damascene structure DS3 in FIG. 1. As shown in FIG. 1 and FIG. 2, in some embodiments, the pad structure PD may have a rectangular structure in the top view diagram, and the lower portion P1 and the upper portion P2 of the dual damascene structure DS may respectively have a rectangular frame structure in the top view diagram. The upper portion P2 may completely cover the lower portion P1 in the vertical direction D1, and the lower portion P1 may be completely disposed on the pad structure PD in the top view diagram. As shown in FIG. 1 and FIG. 3, in some embodiments, pad structure PD may have a rectangular-shaped structure in the top view diagram, a plurality of the dual damascene structures DS may be disposed on the pad structure PD and arranged in the horizontal directions, and the lower portion P1 and the upper portion P2 of each of the dual damascene structures DS may respectively have a rectangular frame structure in the top view diagram. In addition, the top electrodes surrounded by the dual damascene structures DS may be electrically connected with one another or be electrically separated from one another according to some design considerations. As shown in FIG. 1 and FIG. 4, in some embodiments, the pad structure PD may have a circular structure in the top view diagram, the lower portion P1 and the upper portion P2 of the dual damascene structure DS may respectively have a ring structure in the top view diagram, and the upper portion P2 may completely cover the lower portion P1 in the vertical direction D1. As shown in FIG. 1 and FIG. 5, in some embodiments, pad structure PD may have a rectangular-shaped structure in the top view diagram, a plurality of the dual damascene structures DS with a circular structure in the top view diagram may be disposed on the pad structure PD and arranged in the horizontal directions, and the lower portion P1 and the upper portion P2 of each of the dual damascene structures DS may respectively have a ring structure in the top view diagram. In addition, the top electrodes surrounded by the dual damascene structures DS may be electrically connected with one another or be electrically separated from one another according to some design considerations. It is worth noting that the top view condition of the bottom electrode BE in the present invention may include but is not limited to the conditions shown in FIGS. 2-5. In other words, the lower portion P1 and the upper portion P2 of the dual damascene structure DS may have a structure with other suitable closed figure in the top view diagram for surrounding the corresponding capacitor dielectric layer 52 and the top electrode TE in the horizontal directions orthogonal to the vertical direction D1 according to some design considerations, and the pad structure PD may have other suitable shapes in the top view diagram according to some design considerations. In addition, the above-mentioned widths of the lower portion P1 and the upper portion P2 of the dual damascene structure DS may be regarded as the line widths of the closed figures of the lower portion P1 and the upper portion P2 in the top view diagram illustrating the bottom electrode BE, but not limited thereto.

As shown in FIG. 1, the stop layer 18 is disposed on the dielectric layer 12, the dielectric layer 20 is disposed on the stop layer 18, the stop layer 28 is disposed on the dielectric layer 20, the dielectric layer 30 is disposed on the stop layer 28, the stop layer 38 is disposed on the dielectric layer 30, and the dielectric layer 40 is disposed on the stop layer 38. The conductive line M1 and the pad structure PD may be disposed in the dielectric layer 12, the conductive line M1 and the pad structure PD may be formed concurrently by the same manufacturing process, and both of the conductive line M1 and the pad structure PD may include a barrier layer 14 and an electrically conductive material 16 disposed on the barrier layer 14 accordingly, but not limited thereto. The upper portion P12 of the first dual damascene structure DS1 may be disposed in the dielectric layer 20, the lower portion P11 may be partly disposed in the dielectric layer 20, and the lower portion P11 may penetrate through the stop layer 18 in the vertical direction D1. In some embodiments, the first damascene structure DS1, the conductive line M2, and the via conductor V1 may be formed concurrently by the same manufacturing process, and the first damascene structure DS1, the conductive line M2, and the via conductor V1 may all include a first barrier layer (such as a barrier layer 24) and a first electrically conductive material (such as an electrically conductive material 26) disposed on the barrier layer 24 accordingly, but not limited thereto. The upper portion P22 of the second dual damascene structure DS2 may be disposed in the dielectric layer 30, the lower portion P21 may be partly disposed in the dielectric layer 30, and the lower portion P21 may penetrate through the stop layer 28 in the vertical direction D1. In addition, the second damascene structure DS2, the conductive line M3, and the via conductor V2 may be formed concurrently by the same manufacturing process, and the second damascene structure DS2, the conductive line M3, and the via conductor V2 may all include a second barrier layer (such as a barrier layer 34) and a second electrically conductive material (such as an electrically conductive material 36) disposed on the barrier layer 34 accordingly, but not limited thereto. The upper portion P32 of the third dual damascene structure DS3 may be disposed in the dielectric layer 40, the lower portion P31 may be partly disposed in the dielectric layer 40, and the lower portion P31 may penetrate through the stop layer 38 in the vertical direction D1. In addition, the third damascene structure DS3, the conductive line M4, and the via conductor V3 may be formed concurrently by the same manufacturing process, and the third damascene structure DS3, the conductive line M4, and the via conductor V3 may all include a barrier layer 44 and an electrically conductive material 46 disposed on the barrier layer 44 accordingly, but not limited thereto. In addition, the barrier layer 24 may be partly disposed between the electrically conductive material 16 and the electrically conductive material 26 in the vertical direction D1, the barrier layer 34 may be partly disposed between the electrically conductive material 26 and the electrically conductive material 36 in the vertical direction D1, and the barrier layer 44 may be partly disposed between the electrically conductive material 36 and the electrically conductive material 46 in the vertical direction D1.

In some embodiments, the capacitor structure 101 may further include a first metal layer 50 and a second metal layer 54. The first metal layer 50 is disposed between the bottom electrode BE and the capacitor dielectric layer 52, the second metal layer 54 is disposed between the capacitor dielectric layer 52 and the top electrode TE, and the first metal layer 50, the second metal layer 54, and the capacitor dielectric layer 52 disposed between the first metal layer 50 and the second metal layer 54 may constitute a metal-insulator-metal (MIM) capacitor, but not limited thereto. In some embodiments, the MIM capacitor described above may be disposed conformally on the inner surface of the bottom electrode BE substantially, and the surface area of the capacitor dielectric layer 52 may be increased by the recessed condition formed with the dual damascene structures DS for enhancing the capacitance of the MIM capacitor accordingly. In some embodiments, the first metal layer 50 and the second metal layer 54 may respectively include a single layer or multiple layers of metallic electrically conductive materials, such as titanium, tantalum, titanium nitride, tantalum nitride, or other suitable electrically conductive metal materials, and the capacitor dielectric layer 52 may include a single layer or multiple layers of dielectric materials, such as silicon nitride, silicon-rich silicon nitride, silicon oxide, silicon oxynitride, a high dielectric constant (high-k) dielectric material (such as zirconium oxide, hafnium oxide, tantalum oxide, titanium oxide, or aluminum oxide), or other suitable dielectric materials. In some embodiments, the first metal layer 50 may be directly connected with the bottom electrode BE (such as each of the dual damascene structures DS and the pad structure PD), and a part of the first metal layer 50 may be disposed under the upper portion of the dual damascene structure DS in the vertical direction D1 and disposed between the lower portion of the dual damascene structure DS and the capacitor dielectric layer 52 in the horizontal direction (such as the horizontal direction D2, but not limited thereto). For example, a part of the first metal layer 50 may be disposed under the upper portion P12 of the first dual damascene structure DS1 (such as the barrier layer 24 and the electrically conductive material 26 in the upper portion P12) in the vertical direction D1 and disposed between the capacitor dielectric layer 52 and the lower portion P11 of the first dual damascene structure DS1 (such as the barrier layer 24 and the electrically conductive material 26 in the lower portion P11) in the horizontal direction D2.

In some embodiments, a part of the capacitor dielectric layer 52 may be disposed under the upper portion of the dual damascene structure DS in the vertical direction D1 and disposed between the lower portion of the dual damascene structure DS and the top electrode TE in the horizontal direction (such as the horizontal direction D2, but not limited thereto) and/or disposed between lower portion of the dual damascene structure DS and the second metal layer 54 in the horizontal direction D2. For example, a part of the capacitor dielectric layer 52 may be disposed under the upper portion P12 of the first dual damascene structure DS1 (such as the barrier layer 24 and the electrically conductive material 26 in the upper portion P12) in the vertical direction D1 and disposed between the top electrode TE and the lower portion P11 of the first dual damascene structure DS1 (such as the barrier layer 24 and the electrically conductive material 26 in the lower portion P11) in the horizontal direction D2. Additionally, in some embodiments, the bottom surface of the first metal layer 50 may directly contact the pad structure PD, and the bottom surface of the first metal layer 50 may be lower than the top surface of the pad structure PD and higher than the bottom surface of the pad structure PD in the vertical direction D1, but not limited thereto. In some embodiments, because of the influence of the dual damascene structures DS, the top electrode TE may include protruding parts extending towards the lower portions of the dual damascene structures DS in the horizontal directions, and a width of the top electrode TE surrounded by the lower portion of the dual damascene structure DS in the horizontal direction may be greater than a width of the top electrode TE surrounded by the upper portion of the dual damascene structure DS in the horizontal direction accordingly, but not limited thereto. For example, a width W3 of the top electrode TE surrounded by the lower portion P11 of the first dual damascene structure DS1 in the horizontal direction D2 may be greater than a width W4 of the top electrode TE surrounded by the upper portion P12 of the first dual damascene structure DS1 in the horizontal direction D2, and the width of the top electrode TE may also be regarded as a length of the top electrode TE in the horizontal direction. Additionally, in some embodiments, because of the influence of the manufacturing condition, a part of the first metal layer 50 and a part of the capacitor dielectric layer 52 may be sandwiched between the upper portion of the dual damascene structure DS and the stop layer that the lower portion of this dual damascene structure DS penetrates through in the vertical direction D1. For example, a part of the first metal layer 50 and a part of the capacitor dielectric layer 52 may be sandwiched between the upper portion P12 of the first dual damascene structure DS1 and the stop layer 18 in the vertical direction D1, but not limited thereto.

In some embodiments, the capacitor structure 101 may further include a stop layer 48, a patterned mask layer 56, a dielectric layer 58, a connection structure CT1, and a connection structure CT2. The stop layer 48 may be disposed on the dielectric layer 40 and cover the bottom electrode BE (such as the third dual damascene structure DS3) and the conductive line M4. The top electrode TE, the second metal layer 54, the capacitor dielectric layer 52, and the first metal layer 50 may penetrate through the stop layer 48 in the vertical direction D1, and the second metal layer 54, the capacitor dielectric layer 52, and the first metal layer 50 may be partly disposed above the stop layer 48 in the vertical direction D1. The patterned mask layer 56 may be disposed on the second metal layer 54 and the top electrode TE, the patterned mask layer 56 may include an insulation material, and the dielectric layer 58 may be disposed on the stop layer 48 and cover the patterned mask layer 56. The connection structure CT1 may penetrate through the dielectric layer 58 and the stop layer 48 in the vertical direction D1 for contacting and being electrically connected with the dual damascene structure DS in the bottom electrode BE (such as the third dual damascene structure DS3), and the connection structure CT2 may penetrate through the dielectric layer 58 and the patterned mask layer 56 in the vertical direction D1 for contacting and being electrically connected with the top electrode TE. In some embodiments, the connection structure CT1 and the connection structure CT2 may include dual damascene structures, respectively, the connection structure CT1, the connection structure CT2, and the conductive line M5 and the via conductor V4 in the interconnection structure CS may be formed concurrently by the same manufacturing process, and connection structure CT1, the connection structure CT2, the conductive line M5, and the via conductor V4 may all include a barrier layer 60 and an electrically conductive material 62 disposed on the barrier layer 60 accordingly, but not limited thereto.

In some embodiments, the dielectric layer 12, the dielectric layer 20, the dielectric layer 30, the dielectric layer 40, and the dielectric layer 58 may include silicon oxide, fluorosilicate glass (FSG), a low dielectric constant (low-k) dielectric material, an ultra-low dielectric constant (ULK) dielectric material, or other suitable dielectric materials. The low-k dielectric material and the ULK dielectric material described above may include dielectric materials with relatively lower dielectric constant (such as but not limited to dielectric constant lower than 2.9 and 2.7, respectively), but not limited thereto. In addition, the stop layer 18, the stop layer 28, the stop layer 38, and the stop layer 48 may include nitrogen doped carbide (NDC, such as nitrogen doped silicon carbide), silicon nitride, silicon oxycarbide (SiOC), silicon oxycarbonitride (SiOCN), or other suitable dielectric materials. The barrier layer 14, the barrier layer 24, the barrier layer 34, the barrier layer 44, and the barrier layer 60 may include titanium nitride, tantalum nitride, or other suitable electrically conductive barrier materials. The electrically conductive material 16, the electrically conductive material 26, the electrically conductive material 36, the electrically conductive material 46, the electrically conductive material 62, and the top electrode TE may include a material with relatively low electrical resistivity, such as copper, aluminum, tungsten, and so forth. It is worth noting that, because the bottom electrode BE and a part of the interconnection structure CS may be formed concurrently by the same manufacturing process, the bottom electrode BE and the top electrode TE may be formed with the electrically conductive materials with relatively low electrical resistivity for improving the operation performance of the capacitor structure (such as improving the Q-factor, but not limited thereto). For instance, the electrically conductive material 16, the electrically conductive material 26, the electrically conductive material 36, the electrically conductive material 46, and the top electrode TE may be copper, and the top electrode TE may directly contact the second metal layer 54 because there is no need to dispose a barrier layer between the second metal layer 54 and copper.

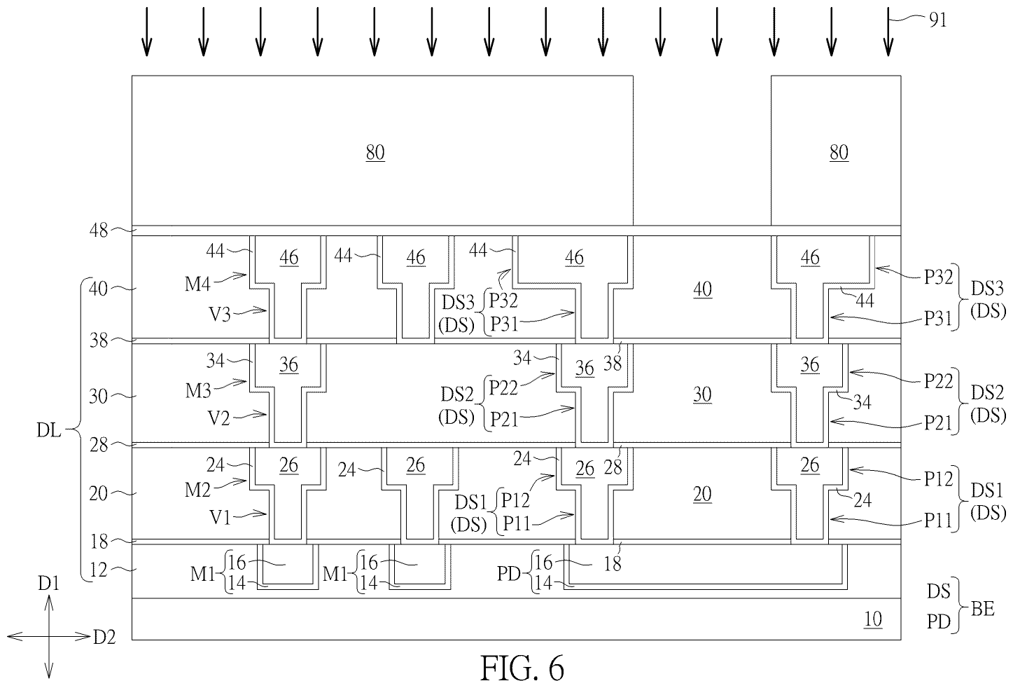

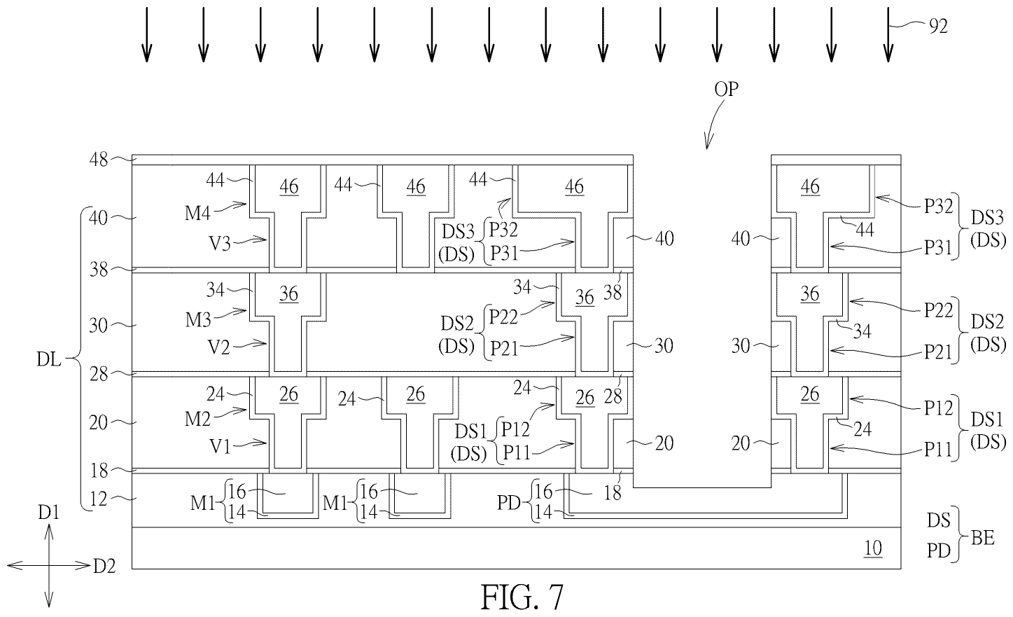

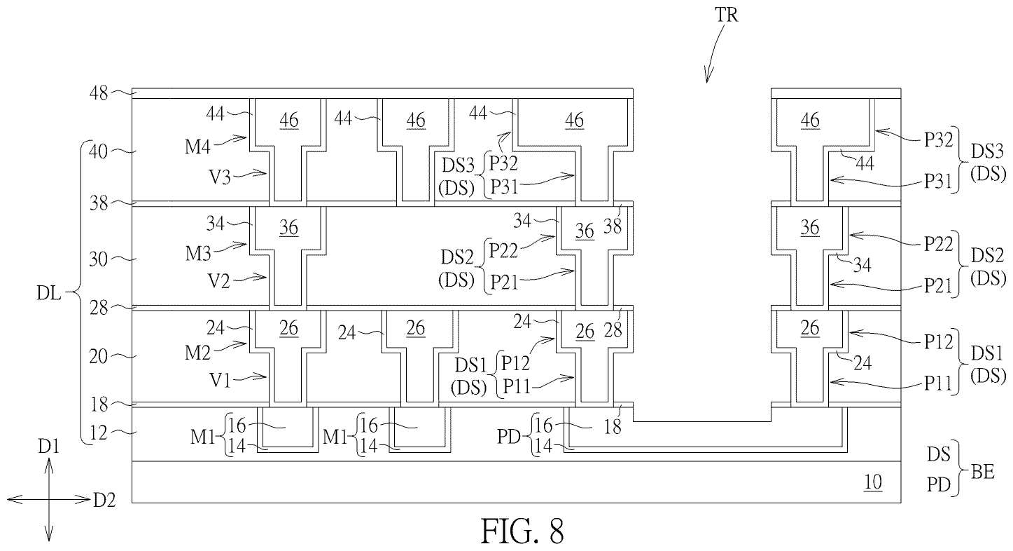

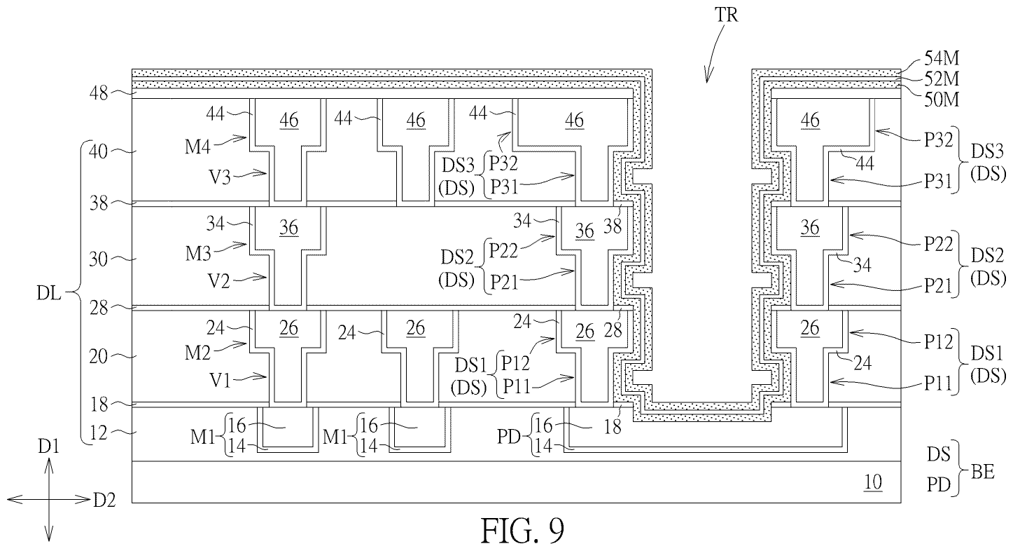

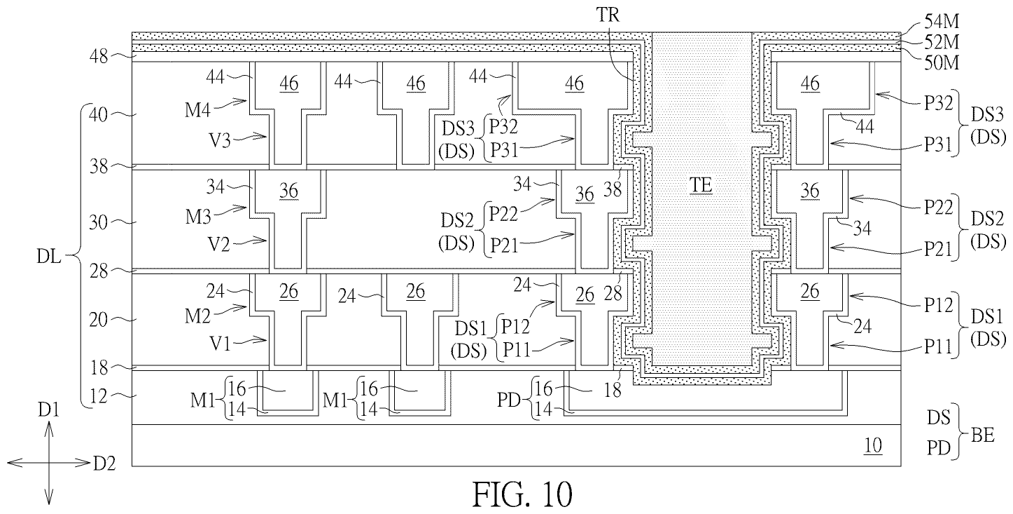

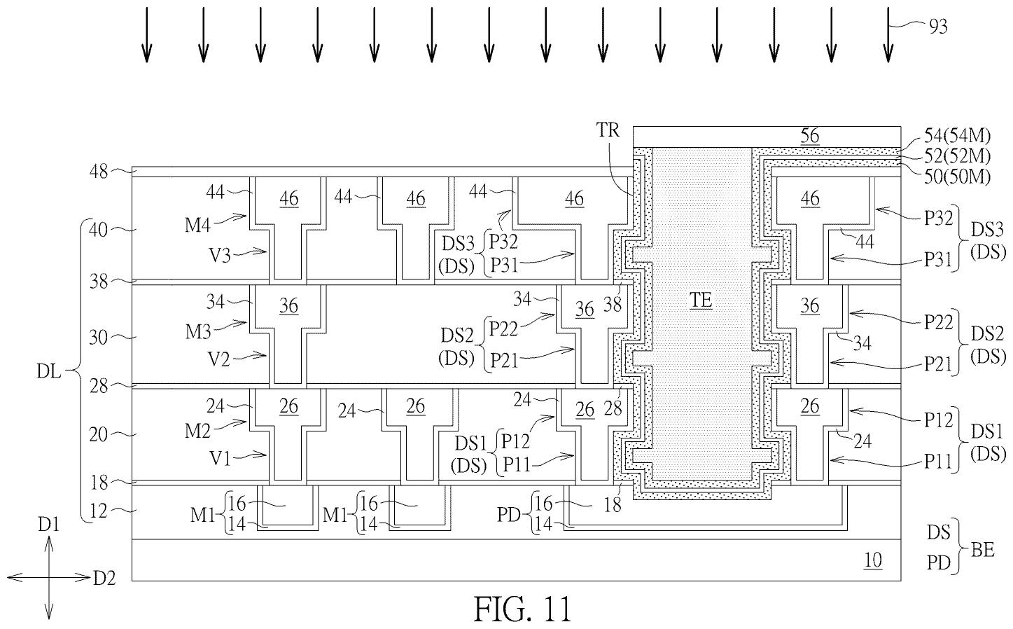

Please refer to FIG. 1 and FIGS. 6-11. FIGS. 6-11 are schematic drawings illustrating a manufacturing method of a capacitor structure according to an embodiment of the present invention, wherein FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, and FIG. 11 is a schematic drawing in a step subsequent to FIG. 10. In some embodiments, FIG. 1 may be regarded as a schematic drawing in a step subsequent to FIG. 11, but not limited thereto. As shown in FIG. 1, the manufacturing method of the capacitor structure 101 may include the following steps. The dielectric stack structure DL is formed on the substrate 10, and the bottom electrode BE is formed in the dielectric stack structure DL. The top electrode TE is formed above the substrate 10, and the bottom electrode BE surrounds the top electrode TE in the horizontal direction (such as the horizontal direction D2, but not limited thereto). The capacitor dielectric layer 52 is formed between the bottom electrode BE and the top electrode TE, and the bottom electrode BE includes a first dual damascene structure DS1 surrounding the capacitor dielectric layer 52 and the top electrode TE in the horizontal direction D2.

Specifically, the manufacturing method of the capacitor structure in this embodiment may include but is not limited to the following steps. As shown in FIG. 6, some conductive lines and some via conductors of the interconnection structure described above and the bottom electrode BE may be formed in the dielectric stack structure DL, and the stop layer 48 may be formed on the stack structure DL. In addition, before the first metal layer, the capacitor dielectric layer, the second metal layer, and the top electrode described above are formed, a part of the dielectric stack structure DL may be surrounded by the bottom electrode BE in the horizontal direction (such as the horizontal direction D2, but not limited thereto). Subsequently, as shown in FIG. 6 and FIG. 7, a patterned mask layer 80 may be formed on the stop layer 48 and an etching process 91 using the patterned mask layer 80 as a mask may be performed for forming an opening OP, and the opening OP may be elongated in the vertical direction D1 and penetrate through the dielectric stack structure DL surrounded by the bottom electrode BE in the horizontal direction D2. In other words, a part of the dielectric stack structure DL surrounded by the bottom electrode BE in the horizontal direction D2 may be removed by the etching process 91 for forming the opening OP, and the dielectric stack structure DL may be partly located between the opening OP and the bottom electrode BE in the horizontal direction D2. For example, a part of the dielectric layer 20 and a part of the stop layer 18 may be located between the opening OP and the first dual damascene structure DS in the horizontal direction D2. Additionally, in some embodiments, the opening OP may penetrate through the stop layer 48, the dielectric layer 40, the stop layer 38, the dielectric layer 30, the stop layer 28, the dielectric layer 20, and the stop layer 18 in the vertical direction D1 for being partly located in the pad structure PD and partially exposing the electrically conductive material 16 of the pad structure PD. The etching process 91 may include an ion beam etching (IBE) process or the suitable etching approaches. The patterned mask layer 80 may include photoresist or other suitable mask materials, and the patterned mask layer 80 may be removed after the etching process 91.

As shown in FIGS. 6-8, an etching process 92 may be performed after the etching process 91 for removing at least a portion of the dielectric stack structure DL located between the opening OP and the bottom electrode BE in the horizontal direction D2 (such as the dielectric layer 20m the dielectric layer 30, and the dielectric layer 40 located between the opening OP and the dual damascene structure DS), and the opening OP may be partially expanded in the horizontal direction by the etching process 92 to become a trench TR surrounded by the bottom electrode BE in the horizontal direction D2. In other words, the trench TR may be regarded as being formed by removing at least a part of the dielectric stack structure DL surrounded by the bottom electrode BE in the horizontal direction D2. In some embodiments, the etching process 92 may include a wet etching process, such as a buffer oxide etching (BOE) process or other etching approaches with higher etching selectively for reducing the etching damage to each of the dual damascene structures DS and the pad structure PD in the etching process 92. Therefore, in some embodiments, the stop layers located between the opening OP and the bottom electrode BE in the horizontal direction D2 may not be removed by the etching process 92, but not limited thereto. It is worth noting that the method of forming the trench TR in this embodiment may include but is not limited to the steps illustrated in FIGS. 6-8, and the trench TR shown in FIG. 8 may also be formed by other suitable approaches according to some design considerations.

As shown in FIG. 9, before the top electrode described above is formed, a first metal material 50M, a capacitor dielectric material 52M, and a second metal material 54M may be formed. The first metal material 50M may be formed conformally in the trench TR and on the stop layer 48 substantially, the capacitor dielectric material 52M may be formed conformally on the first metal material 50M substantially, and the second metal material 54M may be formed conformally on the capacitor dielectric material 52M substantially. The first metal material 50M, the capacitor dielectric material 52M, and the second metal material 54M may be partly formed in the trench TR and partly formed outside the trench TR, and the first metal material 50M, the capacitor dielectric material 52M, and the second metal material 54M may be respectively formed by an atomic layer deposition (ALD) process or other suitable approaches. Subsequently, as shown in FIG. 9 and FIG. 10, the top electrode TE may be formed in the trench TR, and the top electrode TE may be partly formed in the trench TR and partly formed outside the trench TR. In some embodiments, an electrically conductive material (such as copper, but not limited thereto) may be formed by electrochemical plating (ECP) or other suitable approaches, and the trench TR may be fully filled with this electrically conductive material and the first metal material 50M, the capacitor dielectric material 52M, and the second metal material 54M formed before this electrically conductive material substantially. A planarization process may then be performed to this electrically conductive material for removing a part of this electrically conductive material, and the remaining part of this electrically conductive material after the planarization process becomes the top electrode TE. The planarization process described above may include a chemical mechanical polishing (CMP) process or other suitable approaches, and this planarization process may stop at the second metal material 54M. It is worth noting that the method of forming the top electrode TE in this embodiment may include but is not limited to the steps illustrated in FIGS. 6-10, and the top electrode TE shown in FIG. 10 may also be formed by other suitable approaches according to other design considerations.

As shown in FIG. 11, after the top electrode TE is formed, a patterned mask layer 56 may be formed on the top electrode TE and the second metal material 54M, and a patterning process 93 using the patterned mask layer 56 as a mask may be performed. A portion of the second metal material 54M located outside the trench TR, a portion of the capacitor dielectric material 52M located outside the trench TR, and a portion of the first metal material 50M located outside the trench TR may be removed by the patterning process 93. The second metal material 54M, the capacitor dielectric material 52M, and the first metal material 50M may be patterned to be the second metal layer 54, the capacitor dielectric layer 52, and the first metal layer 50, respectively, by the patterning process 93. The patterning process 93 may include an etching process or other suitable patterning approaches. It is worth noting that the method of forming the second metal layer 54, the capacitor dielectric layer 52, and the first metal layer 50 in this embodiment may include but is not limited to the steps illustrated in FIGS. 9-11, and the second metal layer 54, the capacitor dielectric layer 52, and the first metal layer 50 shown in FIG. 11 may also be formed by other suitable approaches according to other design considerations. Subsequently, as shown in FIG. 1, the dielectric layer 58, the via conductor V4, the conductive line M5, the connection structure CT1, and the connection structure CT2 may be formed for forming the capacitor structure 101. In addition, the capacitor unit formed by the method described above may be regarded as a deep trench capacitor, but not limited thereto.

The following description will detail the different embodiments of the present invention. To simplify the description, the following description will detail the dissimilarities among different embodiments and the identical features will not be redundantly described. In addition, identical components in each of the following embodiments are marked with identical symbols for making it easier to understand the differences between the embodiments.

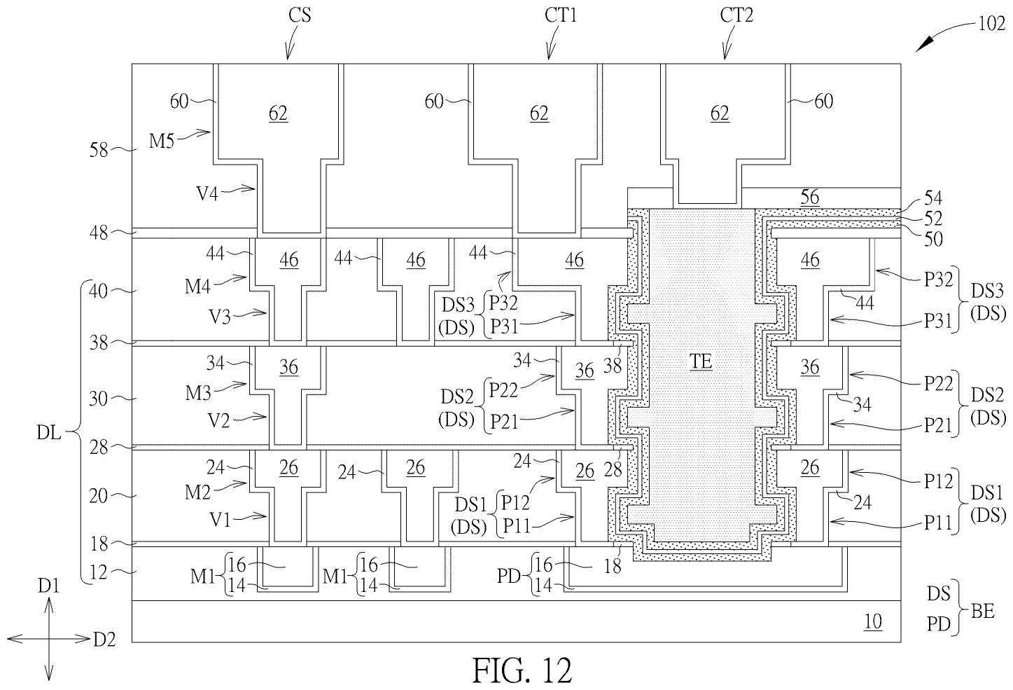

Please refer to FIG. 12. FIG. 12 is a schematic drawing illustrating a capacitor structure 102 according to a second embodiment of the present invention. As shown in FIG. 12, in the capacitor structure 102, the first metal layer 50 may be directly connected with the electrically conductive material in each of the dual damascene structures DS (such as the electrically conductive material 26 in the first dual damascene structure DS1), and a part of the barrier layer in each of the dual damascene structures DS (such as a part of the barrier layer facing the top electrode TE) may be removed (such as being removed by the process of forming the trench TR illustrated in FIGS. 7-8) before the first metal layer 50 is formed.

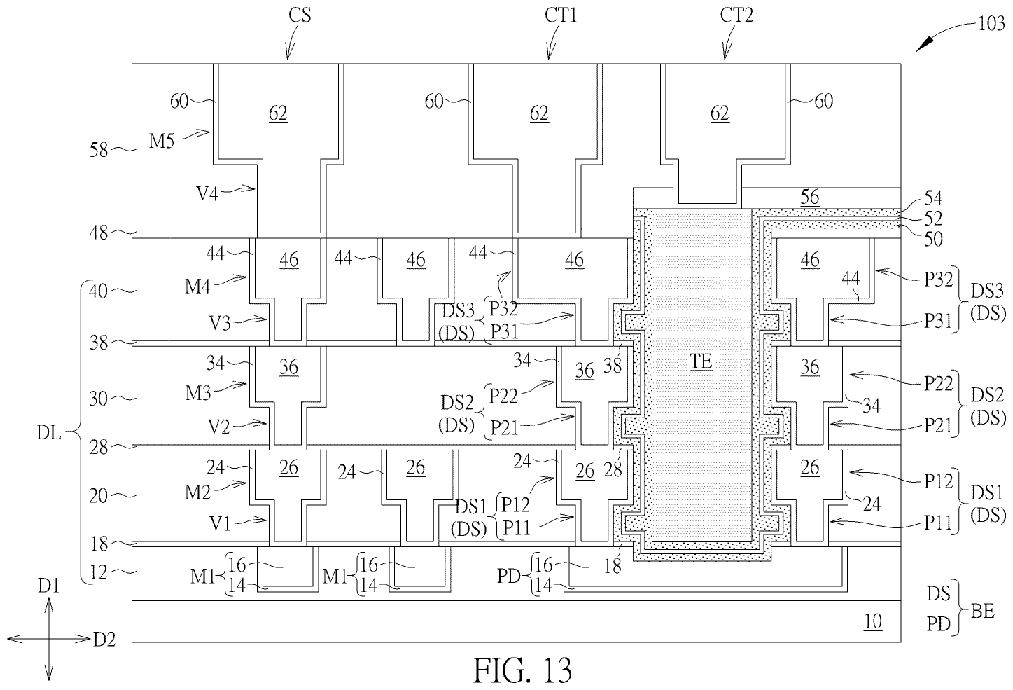

Please refer to FIG. 13. FIG. 13 is a schematic drawing illustrating a capacitor structure 103 according to a third embodiment of the present invention. As shown in FIG. 13, in the capacitor structure 103, because the length of the upper portion of each dual damascene structure DS in the vertical direction D1 is greater and/or the length of the lower portion of each dual damascene structure DS in the vertical direction D1 is smaller, the top electrode TE may not include the protruding parts extending towards the lower portions of the dual damascene structures DS in the horizontal directions. Therefore, the width of the top electrode TE surrounded by the lower portion of the dual damascene structure DS in the horizontal direction may be substantially equal to the width of the top electrode TE surrounded by the upper portion of the dual damascene structure DS in the horizontal direction.

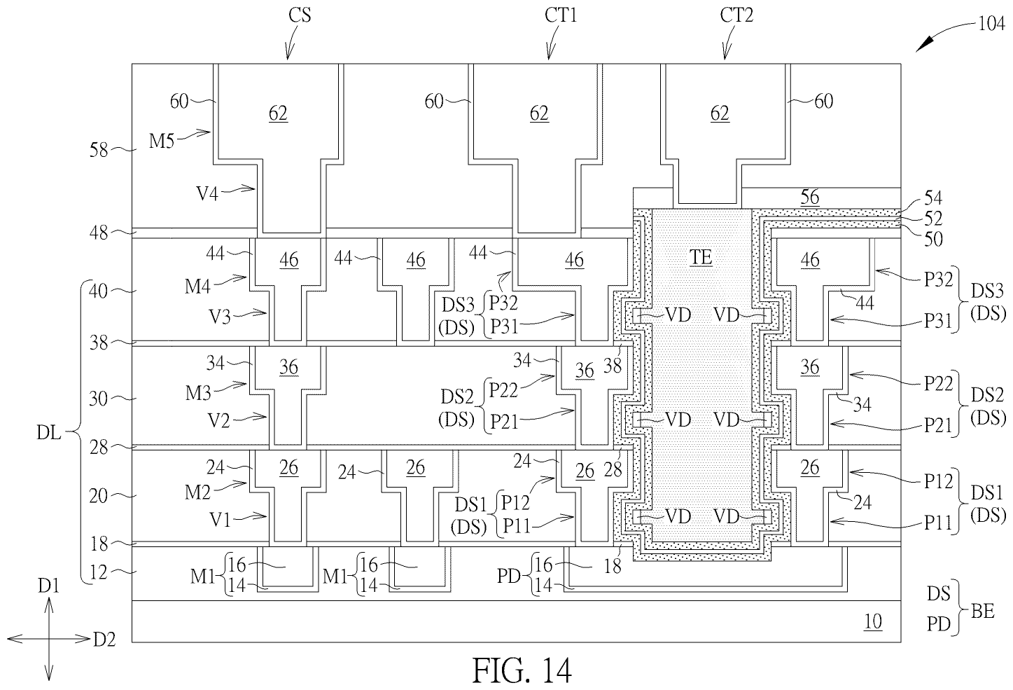

Please refer to FIG. 14. FIG. 14 is a schematic drawing illustrating a capacitor structure 104 according to a fourth embodiment of the present invention. As shown in FIG. 14, in the capacitor structure 104, because of the influence of the process condition of forming the top electrode TE (such as the condition of the EPC process, but not limited thereto), the capacitor structure 104 may further include a void VD formed in the top electrode TE and/or located between the top electrode TE and the second metal layer 54. For example, after the top electrode TE is formed, the void VD may be disposed between the second metal layer 54 and the protruding part of the top electrode TE extending towards the lower portion of the dual damascene structure DS in the horizontal direction, and the electrical connection between the top electrode TE and the second metal layer 54 will not be influenced by the void VD. In addition, the void VD in this embodiment may be formed in the capacitor structures of the embodiments described above.

To summarize the above descriptions, according to the capacitor structure and the manufacturing method thereof in the present invention, the bottom electrode including the dual damascene structure may be disposed in the dielectric stack structure and surround the capacitor dielectric layer and the top electrode, and the surface area of the capacitor dielectric layer may be increased by the recessed condition formed with the dual damascene structures for enhancing the capacitance of the MIM capacitor accordingly. In addition, the bottom electrode and a part of the interconnection structure may be formed concurrently by the same manufacturing process for process integration, and the bottom electrode and the top electrode may be made of the electrically conductive material with relatively low electrical resistivity for improving the operation performance of the capacitor structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitor structure, comprising:
a dielectric stack structure disposed on a substrate, wherein the dielectric stack structure comprises:
a stop layer, and
a dielectric layer disposed on the stop layer;
a bottom electrode disposed in the dielectric stack structure;
a top electrode disposed above the substrate, wherein the bottom electrode surrounds the top electrode in a horizontal direction; and
a capacitor dielectric layer disposed between the bottom electrode and the top electrode, wherein the bottom electrode comprises a first dual damascene structure surrounding the capacitor dielectric layer and the top electrode in the horizontal direction, an upper portion of the first dual damascene structure is disposed in the dielectric layer, a lower portion of the first dual damascene structure is partly disposed in the dielectric layer, and the lower portion of the first dual damascene structure penetrates through the stop layer in a vertical direction.

2. The capacitor structure according to claim 1, wherein a width of the lower portion of the first dual damascene structure is less than a width of the upper portion of the first dual damascene structure, and a part of the capacitor dielectric layer is disposed under the upper portion of the first dual damascene structure in the vertical direction.

3. The capacitor structure according to claim 1, wherein a width of the top electrode surrounded by the lower portion of the first dual damascene structure in the horizontal direction is greater than a width of the top electrode surrounded by the upper portion of the first dual damascene structure in the horizontal direction.

4. The capacitor structure according to claim 1, wherein the first dual damascene structure comprises:
a first barrier layer; and
a first electrically conductive material disposed on the first barrier layer, wherein a part of the capacitor dielectric layer is disposed under the first electrically conductive material in the vertical direction and disposed between the first electrically conductive material and the top electrode in the horizontal direction.

5. The capacitor structure according to claim 4, wherein the part of the capacitor dielectric layer is disposed under the first barrier layer in the vertical direction and disposed between the first barrier layer and the top electrode in the horizontal direction.

6. The capacitor structure according to claim 4, further comprising:
a first metal layer disposed between the bottom electrode and the capacitor dielectric layer; and
a second metal layer disposed between the capacitor dielectric layer and the top electrode, wherein a part of the first metal layer is disposed under the first electrically conductive material in the vertical direction and disposed between the first electrically conductive material and the capacitor dielectric layer in the horizontal direction.

7. The capacitor structure according to claim 6, wherein the part of the first metal layer is disposed under the first barrier layer in the vertical direction and disposed between the first barrier layer and the capacitor dielectric layer in the horizontal direction.

8. The capacitor structure according to claim 6, wherein the first metal layer is directly connected with the first electrically conductive material.

9. The capacitor structure according to claim 6, wherein the bottom electrode further comprises:
a pad structure, wherein the first dual damascene structure is disposed on the pad structure, and the first metal layer is directly connected with the pad structure.

10. The capacitor structure according to claim 4, wherein the bottom electrode further comprises:
a second dual damascene structure disposed on the first dual damascene structure, wherein the second dual damascene structure comprises:
a second barrier layer; and
a second electrically conductive material disposed on the second barrier layer, wherein the second barrier layer is disposed between the second electrically conductive material and the first electrically conductive material in the vertical direction.

11. The capacitor structure according to claim 6, further comprising:
a void disposed between the top electrode and the second metal layer.

12. A manufacturing method of a capacitor structure, comprising:
forming a dielectric stack structure and a bottom electrode on a substrate, wherein the bottom electrode is located in the dielectric stack structure, and the bottom electrode comprises:
a pad structure; and
a first dual damascene structure disposed on the pad structure, wherein a width of a lower portion of the first dual damascene structure is less than a width of an upper portion of the first dual damascene structure, and a part of the dielectric stack structure is surrounded by the bottom electrode in a horizontal direction;
removing at least a part of the dielectric stack structure surrounded by the bottom electrode in the horizontal direction for forming a trench surrounded by the bottom electrode in the horizontal direction; and
forming a metal-insulator-metal (MIM) capacitor after the trench is formed, wherein at least a part of the MIM capacitor is formed in the trench and formed conformally on surfaces of the first dual damascene structure and the pad structure.

13. The manufacturing method of the capacitor structure according to claim 12, wherein a method of forming the trench comprises:
forming an opening penetrating through the dielectric stack structure surrounded by the bottom electrode in the horizontal direction, wherein the opening is elongated in a vertical direction, and the dielectric stack structure is partly located between the opening and the bottom electrode in the horizontal direction; and
performing an etching process for removing at least a portion of the dielectric stack structure located between the opening and the bottom electrode in the horizontal direction, wherein the opening is partially expanded in the horizontal direction to become the trench by the etching process.

14. The manufacturing method of the capacitor structure according to claim 12, further comprising:
forming a top electrode in the trench, wherein the bottom electrode surrounds the top electrode in the horizontal direction, and the MIM capacitor comprises:
a first metal layer;
a capacitor dielectric layer, wherein the first metal layer is located between the bottom electrode and the capacitor dielectric layer; and
a second metal layer located between the capacitor dielectric layer and the top electrode.

15. The manufacturing method of the capacitor structure according to claim 14, wherein a method of forming the capacitor dielectric layer comprises:
forming a capacitor dielectric material before the top electrode is formed, wherein the capacitor dielectric material is partly formed in the trench and partly formed outside the trench; and
performing a patterning process after the top electrode is formed, wherein a portion of the capacitor dielectric material located outside the trench is removed by the patterning process, and the capacitor dielectric material is patterned to be the capacitor dielectric layer by the patterning process.

16. The manufacturing method of the capacitor structure according to claim 15, wherein a method of forming the first metal layer and the second metal layer comprises:
forming a first metal material before the top electrode is formed, wherein the capacitor dielectric material is formed on the first metal material, and the first metal material is partly formed in the trench and partly formed outside the trench; and
forming a second metal material on the capacitor dielectric material before the top electrode is formed, wherein the second metal material is partly formed in the trench and partly formed outside the trench, a portion of the first metal material located outside the trench and a portion of the second metal material located outside the trench are removed by the patterning process, and the first metal material and the second metal material are patterned to be the first metal layer and the second metal layer by the patterning process, respectively.

17. The manufacturing method of the capacitor structure according to claim 14, wherein the first dual damascene structure comprises:
a first barrier layer; and
a first electrically conductive material disposed on the first barrier layer, wherein a part of the first metal layer is disposed under the first electrically conductive material in the vertical direction and disposed between the first electrically conductive material and the capacitor dielectric layer in the horizontal direction.

18. The manufacturing method of the capacitor structure according to claim 17, wherein the first metal layer is directly connected with the first electrically conductive material.

19. The manufacturing method of the capacitor structure according to claim 17, wherein the bottom electrode further comprises:
a second dual damascene structure disposed on the first dual damascene structure, wherein the second dual damascene structure comprises:
a second barrier layer; and
a second electrically conductive material disposed on the second barrier layer, wherein the second barrier layer is disposed between the second electrically conductive material and the first electrically conductive material in the vertical direction.

20. The manufacturing method of the capacitor structure according to claim 14, wherein a void is located between the top electrode and the second metal layer after the top electrode is formed.
